(19) United States
(12) Patent Application Publication
(10) Pub. No.: US 2009/0085151 A1
(43) Pub. Date: Apr. 2, 2009

(54) SEMICONDUCTOR FUSE STRUCTURE AND METHOD

(75) Inventors: Deok-kee Kim, Bedford Hills, NY (US); Wai-kin Li, Beacon, NY (US); Haining Sam Yang, Wappingers Falls, NY (US)

Correspondence Address: SCHMEISER, OLSEN & WATTS, 22 CENTURY HILL DRIVE, SUITE 302, LATHAM, NY, 12110, US

(73) Assignee: INTERNATIONAL BUSINESS MACHINES CORPORATION, Armonk, NY (US)

(21) Appl. No.: 11/863,814

(22) Filed: Sep. 28, 2007

(51) Int. Cl. H01L 29/40; H01L 21/44

(52) U.S. Cl. 257/529; 438/601; 257/E21.476; 257/E29.111

(57) ABSTRACT

An electrical structure and method of forming. The electrical structure includes a semiconductor substrate, an insulator layer formed over and in contact with the semiconductor substrate, and a semiconductor fuse structure formed over the insulator layer. The fuse structure includes a silicon layer and a continuous metallic silicide layer. The continuous metallic silicide layer includes a first section formed over and in contact with a first horizontal section of a top surface of the silicon layer, a second section formed over and in contact with a second horizontal section of the top surface of the silicon layer, and a third section formed within an opening within the top surface of the silicon layer.

### FIELD OF THE INVENTION

The present invention relates to an electrical structure comprising a semiconductor fuse.

### BACKGROUND OF THE INVENTION

Structures generated for programming devices are typically unreliable and subject to failure. Accordingly, there exists a need in the art to overcome at least one of the deficiencies and limitations described herein above.

### SUMMARY OF THE INVENTION

The present invention provides an electrical structure comprising:

a semiconductor substrate;

an insulator layer formed over and in contact with said semiconductor substrate; and

a semiconductor fuse structure, wherein said fuse structure comprises a silicon layer and a continuous metallic silicide layer, wherein said silicon layer is formed over and in contact with a top surface of said insulator layer, wherein said silicon layer comprises an opening extending through a top surface of said silicon layer, wherein said opening comprises a horizontal bottom surface, a first vertical sidewall surface, and a second vertical sidewall surface, wherein said continuous metallic silicide layer comprises a first section formed over and in contact with a first horizontal section of said top surface of said silicon layer, a second section formed over and in contact with a second horizontal section of said top surface of said silicon layer, and a third section formed within said opening, wherein said third section formed within said opening comprises a first vertical portion formed on said first vertical sidewall surface, a second vertical portion formed on said second vertical sidewall surface, and a first horizontal portion formed on said horizontal bottom surface, and wherein said first horizontal portion separates said first vertical portion from said second vertical portion.

The present invention provides an electrical structure comprising:

a semiconductor substrate;

an insulator layer formed over and in contact with said semiconductor substrate; and

a semiconductor fuse structure, wherein said fuse structure comprises a silicon layer and a continuous metallic silicide layer, wherein said silicon layer is formed over and in contact with a top surface of said insulator layer, wherein said silicon layer comprises an opening extending from a top surface of said silicon layer though a bottom surface of said silicon layer to said top surface of said insulator layer, wherein said opening comprises a horizontal bottom surface, a first vertical sidewall surface, and a second vertical sidewall surface, wherein said continuous metallic silicide layer comprises a first section formed over and in contact with a first horizontal section of said top surface of said silicon layer, a second section formed over and in contact with a second horizontal section of said top surface of said silicon layer, and a third section formed within said opening, wherein said third section formed within said opening comprises a first vertical portion formed on said first vertical sidewall surface, a second vertical portion formed on said second vertical sidewall surface, and a first horizontal portion formed on said horizontal bottom surface in contact with said top surface of said insulator layer, and wherein said first horizontal portion separates said first vertical portion from said second vertical portion.

The present invention provides a method for forming an electrical structure comprising:

providing a semiconductor substrate;

forming an insulator layer over and in contact with said semiconductor substrate; and forming a semiconductor fuse structure, wherein said fuse structure comprises a silicon layer and a continuous metallic silicide layer, and wherein said forming said semiconductor fuse structure comprises:

forming said silicon layer over and in contact with a top surface of said insulator layer,

forming an opening extending through a top surface of said silicon layer, wherein said opening comprises a horizontal bottom surface, a first vertical sidewall surface, and a second vertical sidewall surface; and

forming said continuous metallic silicide layer over said silicon layer, wherein said continuous metallic silicide layer comprises a first section formed over and in contact with a first horizontal section of said top surface of said silicon layer, a second section formed over and in contact with a second horizontal section of said top surface of said silicon layer, and a third section formed within said opening, wherein said third section formed within said opening comprises a first vertical portion formed on said first vertical sidewall surface, a second vertical portion formed on said second vertical sidewall surface, and a first horizontal portion formed on said horizontal bottom surface, and wherein said first horizontal portion separates said first vertical portion from said second vertical portion.

The present invention advantageously provides a simple structure and associated method for generating structures for programming devices.

### BRIEF DESCRIPTION OF THE DRAWINGS

FIG. 1 illustrates a cross sectional view of an electrical structure, in accordance with embodiments of the present invention

FIG. 2 illustrates a cross sectional view of the electrical structure of FIG. 1 after an opening 28a has been formed, in accordance with embodiments of the present invention.

FIG. 3 depicts an alternative to FIG. 1, in accordance with embodiments of the present invention.

FIGS. 4A-4C illustrate a process for generating the electrical structure of FIG. 1, in accordance with embodiments of the present invention.

FIGS. 5A-5C illustrate a process for generating the electrical structure of FIG. 3, in accordance with embodiments of the present invention.

### DETAILED DESCRIPTION OF THE INVENTION

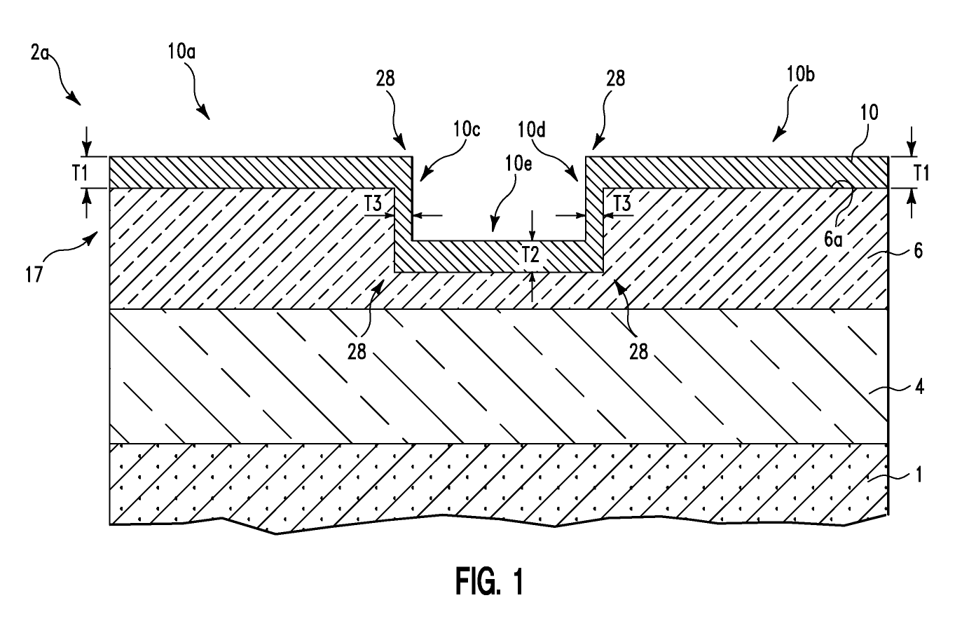

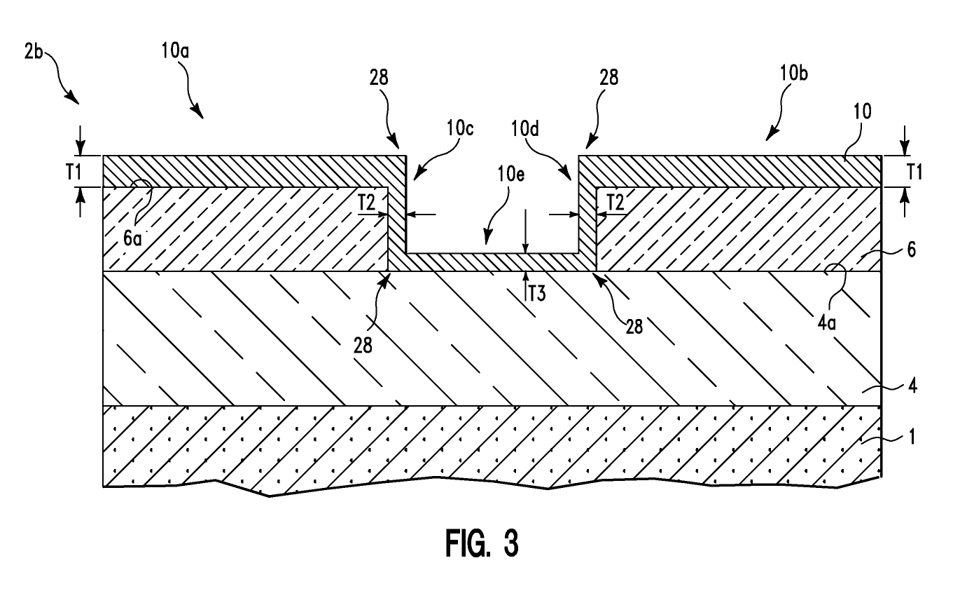

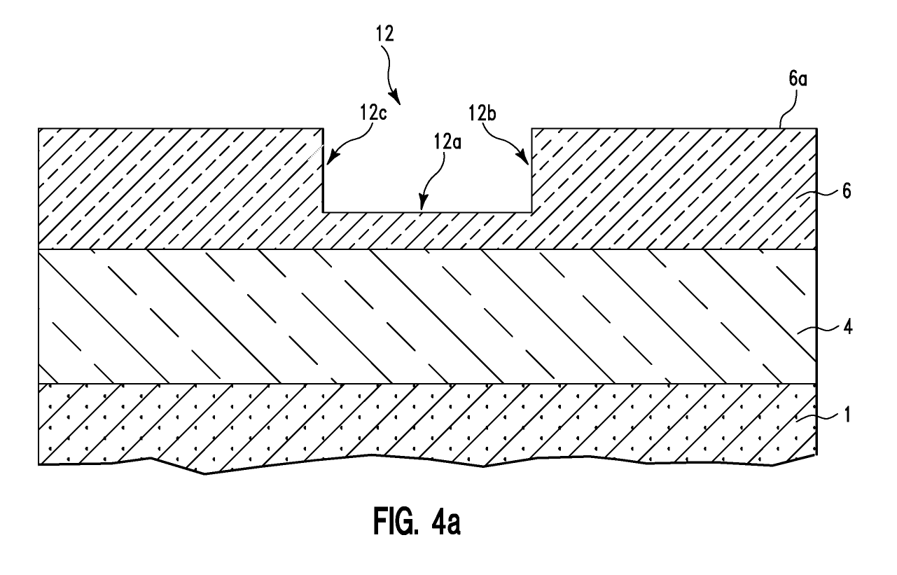

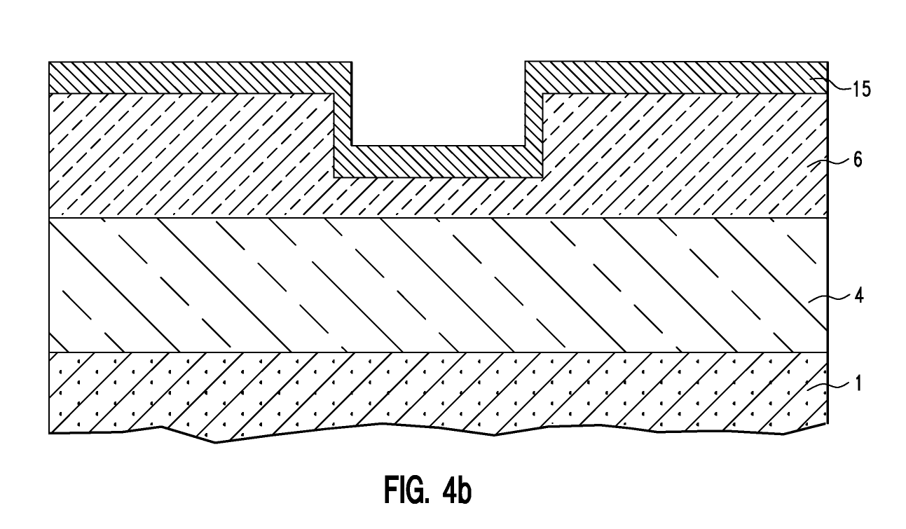

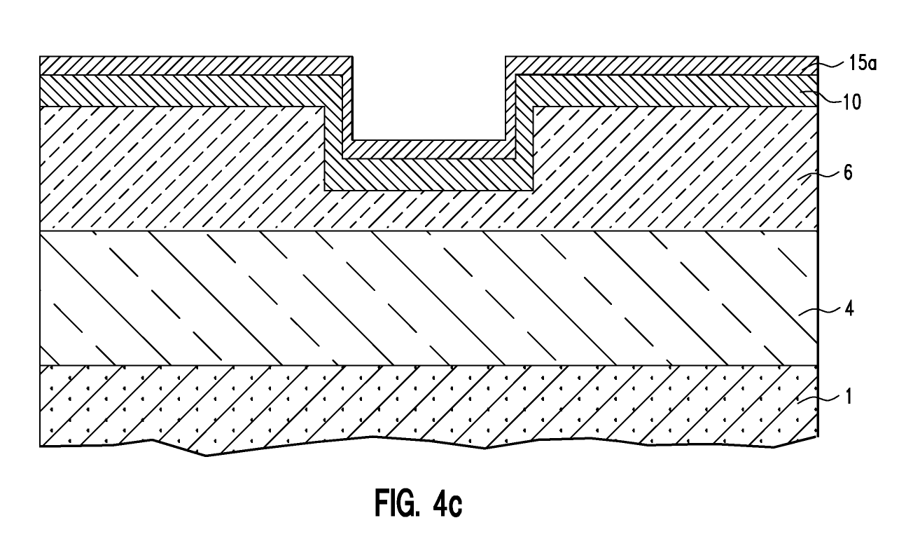

FIG. 1 illustrates a cross sectional view of an electrical structure 2a, in accordance with embodiments of the present invention. Electrical structure 2a comprises a semiconductor substrate 1, an insulator layer 4, and a semiconductor fuse 17 (i.e., an e-fuse). Semiconductor substrate 1 may comprise any type of semiconductor structure including, inter alia, a semiconductor wafer, a semiconductor chip, etc. Insulator layer 4 is formed over and in contact with semiconductor substrate 1. Insulator layer 4 may comprise any type of insulator including, inter alia, an oxide layer, etc. The oxide layer may comprise a buried oxide layer. Semiconductor fuse 17 comprises a silicon layer 6 and a metallic silicide layer 10. Silicon layer 6 is formed over and in contact with insulator layer 4. Silicon layer 6 comprises an opening formed within a top surface 6a of silicon layer 6 (e.g., see opening 12 in FIG. 4). Metallic silicide layer 10 is formed over and in contact with top surface 6a of silicon layer 6 and within the opening formed within top surface 6a of silicon layer 6 (e.g., see opening 12 in FIG. 3). Metallic silicide layer 10 comprises horizontal sections 10a and 10b formed on surface 6a of silicon layer 6 and sections 10c-10e formed within the opening within top surface 6a of silicon layer 6. Sections 10c and 10d are vertical sections formed on sidewalls of the opening within top surface 6a of silicon layer 6 and section 10c is a horizontal section formed on a bottom surface of the opening within top surface 6a of silicon layer 6.

Semiconductor fuse 17 is used for programming various connections within a semiconductor device (e.g., a semiconductor chip). Semiconductor fuse 17 is normally closed or has a relatively lower resistance to allow electric current to flow between section 10a and section 10b of metallic silicide layer 10. When fuse 17 is blown or programmed, it becomes open or comprises an increased resistance between section 10a and section 10b of metallic silicide layer 10. Fuse 17 is a programmable electronic device that is used for a variety of circuit applications including, inter alia, customizing integrated circuits (IC) after production. A single IC configuration may be used for multiple applications by programming fuses (e.g., semiconductor fuse 17) to deactivate select circuit paths. Additionally, semiconductor fuse 17 may be used to program chip identification (ID) after an IC is produced. A series of ones and zeros may be programmed in order to identify an IC so that a user will know its programming and device characteristics. Additionally, fuse 17 may be used in memory devices to improve yields. For example, fuse 17 may be programmed to alter, disconnect or bypass defective memory cells or circuits and allow redundant memory cells to be used in place of cells that are no longer functional.

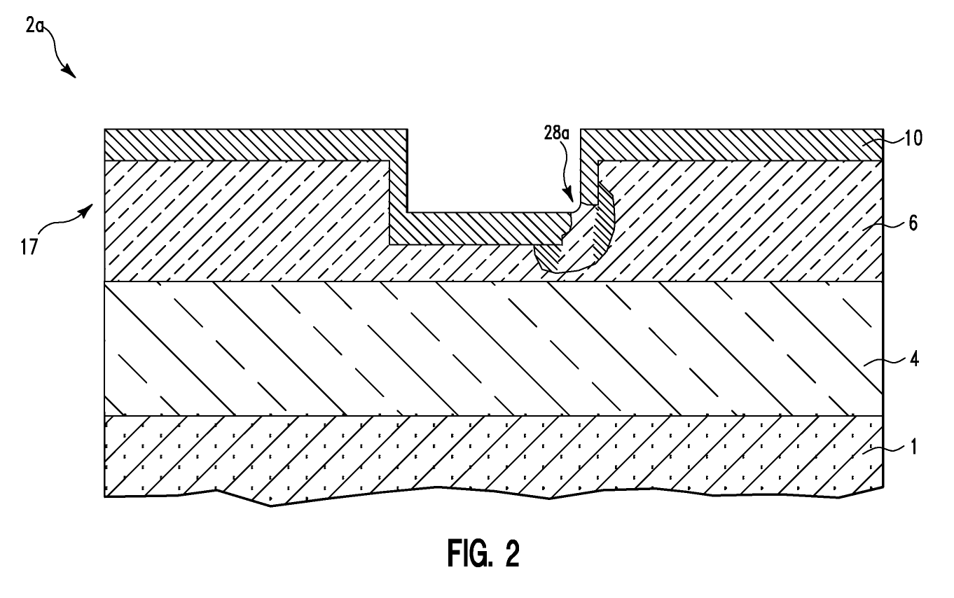

Semiconductor fuse 17 operates on electro-migration properties of metallic silicide layer 10. During a programming process, a current or voltage that is higher than a circuit's normal operating current or voltage (i.e., a circuit or component on semiconductor substrate 1 connected to semiconductor fuse 17) is applied to semiconductor fuse 17. As a result of the programming, an electro-migration process occurs within metallic silicide layer 10 and a discontinuity (i.e., a portion of metallic silicide layer 10 migrates away from the rest of the metallic silicide layer forming a high resistance area) is formed within metallic silicide layer 10 (e.g., see opening 28a in FIG. 2). An increased resistance between section 10a and section 10b of metallic silicide layer 10 is formed thereby restricting current flow through semiconductor fuse 17.

Metallic silicide layer 10 comprises corner sections 28. Corner sections 28 of metallic silicide layer 10 allow for reduced programming current requirements for programming semiconductor fuse 17 thereby minimizing power supply voltage and chip area required for the programming semiconductor fuse 17. Corner sections 28 cause current crowding where a current density is accentuated at corner sections 28. As an input current to semiconductor fuse 17 is increased, a current density is reached at corner sections 28 which causes the electro-migration at corner sections 28. As a result of the electro-migration at corner sections 28, an opening forms (e.g., see opening 28a in FIG. 2) at corner section 28. Electro-migration at corner sections 28 typically occurs if a thickness T1 of horizontal sections 10a and 10b, thickness T3 of vertical sections 10c and 10d, and thickness T2 of horizontal section 10e each comprise a same thickness. Alternatively, thickness T1 of horizontal sections 10a and 10b and thickness T2 of horizontal section 10e may comprise a same thickness while thickness T3 of vertical sections 10c and 10d comprises a different thickness (i.e., from thickness T1 and T2). Alternatively, thickness T1 of horizontal sections 10a and 10b may comprise a different thickness from thickness T2 of horizontal section 10e and thickness T2 may comprise a different thickness from thickness T3 of vertical sections 10c and 10d. Therefore, each of thicknesses T1, T2, and T3 may comprise a same thickness or different thicknesses. Additionally, each of thicknesses T1, T2, and T3 may comprise a thickness that is greater than or less than a thickness each other thickness T1, T2, and T3. Table 1 illustrates various sample thickness configurations for thicknesses T1, T2, and T3.

TABLE 1

T1 = T2 = T3
T1 = T2 > T3
T1 = T2 < T3
T1 < T2 = T3
T1 > T2 = T3
T1 = T3 < T2
T1 = T3 > T2
T1 > T2 > T3
T1 < T2 < T3
T1 > T2 < T3
T1 < T2 > T3

If thicknesses of sections 10a . . . 10e are different then electro-migration will occur at one of sections 10a . . . 10e that comprises a lowest thickness and an opening will form in the section with the lowest thickness. Thicknesses T1-T3 of sections 10a . . . 10e may comprise thicknesses selected from a range of about 3 nm to about 40 nm.

FIG. 2 illustrates a cross sectional view of electrical structure 2a of FIG. 1 after an opening 28a has been formed, in accordance with embodiments of the present invention. Opening 28 is formed as a result of an electro-migration process occurring within metallic silicide layer 10 as described with reference to FIG. 1.

FIG. 3 depicts a first alternative to FIG. 1 illustrating a cross-sectional view of an electrical structure 2b, in accordance with embodiments of the present invention. In contrast with electrical structure 2a FIG. 1, electrical structure 2b of FIG. 3 comprises section 10e formed on a top surface 4a of insulator layer 4.

FIGS. 4A-4C illustrate a process for generating electrical structure 2a of FIG. 1, in accordance with embodiments of the present invention.

FIG. 4A illustrates a cross sectional view of an opening 12 formed within top surface 6a of silicon layer 6, in accordance with embodiments of the present invention. Opening 12 may comprise a trench. Opening 12 comprises sidewalls 12b and 12c and bottom section 12a. Opening 12 may be formed by patterning a photo resist layer formed over silicon layer 6 and using the patterned resist layer to etch silicon layer 6 in order to form opening 12.

FIG. 4B illustrates a cross sectional view of a metallic layer 15 formed on silicon layer 6, in accordance with embodiments of the present invention. Metallic layer 15 is used in the formation of metallic silicide layer 10. Metallic layer 15 may comprise nickel, cobalt, etc. Metallic layer 15 may be formed using a metal sputtering process.

FIG. 4C illustrates a cross sectional view of a portion 15a of metallic layer 15 after metallic silicide layer 10 has been formed, in accordance with embodiments of the present invention. In order to form metallic silicide layer 10, metallic layer 15 and silicon layer are annealed. After metallic silicide layer 10 has been formed, portion 15a is removed or stripped from metallic silicide layer 10 in order to form electrical structure 2a of FIG. 1.

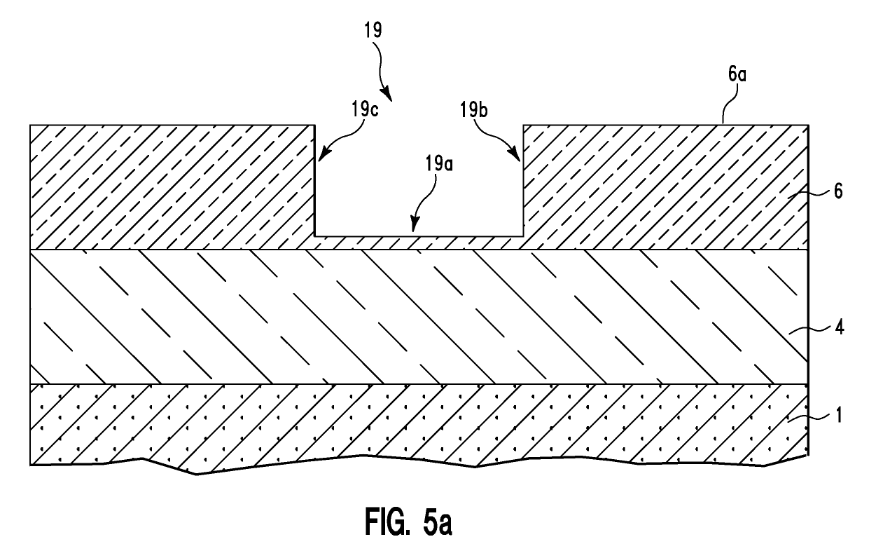

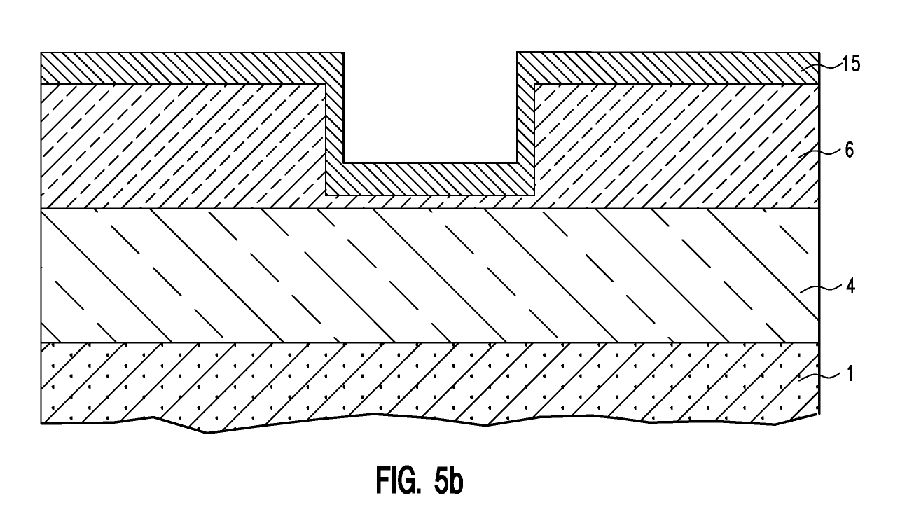

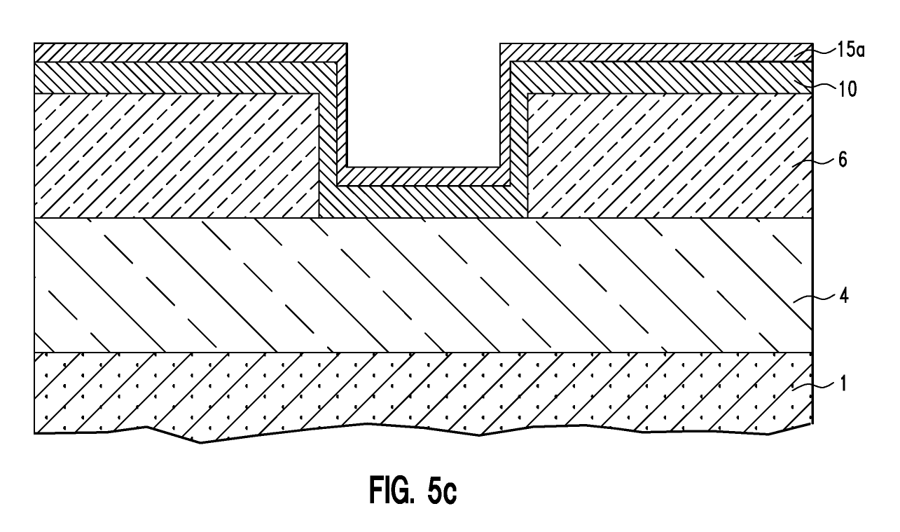

FIGS. 5A-5C illustrate a process for generating electrical structure 2b of FIG. 3, in accordance with embodiments of the present invention.

FIG. 5A illustrates a cross sectional view of an opening 19 formed within top surface 6a of silicon layer 6, in accordance with embodiments of the present invention. Opening 19 may comprise a trench. Opening 19 comprises sidewalls 19b and 19c and bottom section 19a. Opening 19 may be formed by patterning a photo resist layer formed over silicon layer 6 and using the patterned resist layer to etch silicon layer 6 in order to form opening 19. In contrast with opening 12 in FIG. 4a, opening 19 comprises a very thin bottom section 19a.

FIG. 5B illustrates a cross sectional view of a metallic layer 15 formed on silicon layer 6, in accordance with embodiments of the present invention. Metallic layer 15 is used in the formation of metallic silicide layer 10. Metallic layer 15 may comprise nickel, cobalt, etc. Metallic layer 15 may be formed using a metal sputtering process.

FIG. 5C illustrates a cross sectional view of a portion 15a of metallic layer 15 after metallic silicide layer 10 has been formed, in accordance with embodiments of the present invention. In order to form metallic silicide layer 10, metallic layer 15 and silicon layer are annealed. After metallic silicide layer 10 has been formed, portion 15a is removed or stripped from metallic silicide layer 10 in order to form electrical structure 2b of FIG. 3.

While embodiments of the present invention have been described herein for purposes of illustration, many modifications and changes will become apparent to those skilled in the art. Accordingly, the appended claims are intended to encompass all such modifications and changes as fall within the true spirit and scope of this invention.

What is claimed is:

1. An electrical structure comprising:
a semiconductor substrate;
an insulator layer formed over and in contact with said semiconductor substrate; and
a semiconductor fuse structure, wherein said fuse structure comprises a silicon layer and a continuous metallic silicide layer, wherein said silicon layer is formed over and in contact with a top surface of said insulator layer, wherein said silicon layer comprises an opening extending through a top surface of said silicon layer, wherein said opening comprises a horizontal bottom surface, a first vertical sidewall surface, and a second vertical sidewall surface, wherein said continuous metallic silicide layer comprises a first section formed over and in contact with a first horizontal section of said top surface of said silicon layer, a second section formed over and in contact with a second horizontal section of said top surface of said silicon layer, and a third section formed within said opening, wherein said third section formed within said opening comprises a first vertical portion formed on said first vertical sidewall surface, a second vertical portion formed on said second vertical sidewall surface, and a first horizontal portion formed on said horizontal bottom surface, and wherein said first horizontal portion separates said first vertical portion from said second vertical portion.

2. The electrical structure of claim 1, wherein said first horizontal section, said second horizontal section, said first horizontal portion, said first vertical portion, said second vertical portion each comprise an equivalent thickness T1.

3. The electrical structure of claim 1, wherein said first horizontal section, said second horizontal section, and said first horizontal portion each comprise a first thickness T1, wherein said first vertical portion said second vertical portion each comprise a second thickness T2, wherein said first thickness T1 comprises a different thickness than said second thickness T2.

4. The electrical structure of claim 3, wherein said first thickness T1 is greater than said second thickness T2.

5. The electrical structure of claim 1, wherein said first horizontal section and said second horizontal section each comprise a first thickness T1, wherein said first horizontal portion comprises a second thickness T2, and wherein said first thickness T1 comprises a different thickness than said second thickness T2.

6. The electrical structure of claim 5, wherein said first thickness T1 is greater than said second thickness T2.

7. The electrical structure of claim 1, wherein said first horizontal section and said second horizontal section each comprise a first thickness T1, wherein said first horizontal portion comprise a second thickness T2, wherein said first vertical portion said second vertical portion each comprise a third thickness T3, wherein said first thickness T1 comprises a different thickness than said second thickness T2 and said third thickness T3, and wherein said second thickness T2 comprises a different thickness than and said third thickness T3.

8. The electrical structure of claim 7, wherein said first thickness T1 is greater than said second thickness T2, and wherein said second thickness T2 is greater than said third thickness T3.

9. The electrical structure of claim 7, wherein said first thickness T1 is greater than said second thickness T2, and wherein said second thickness T2 is less than said third thickness T3.

10. An electrical structure comprising:
a semiconductor substrate;
an insulator layer formed over and in contact with said semiconductor substrate; and
a semiconductor fuse structure, wherein said fuse structure comprises a silicon layer and a continuous metallic silicide layer, wherein said silicon layer is formed over and in contact with a top surface of said insulator layer, wherein said silicon layer comprises an opening extending from a top surface of said silicon layer though a bottom surface of said silicon layer to said top surface of said insulator layer, wherein said opening comprises a horizontal bottom surface, a first vertical sidewall surface, and a second vertical sidewall surface, wherein said continuous metallic silicide layer comprises a first section formed over and in contact with a first horizontal section of said top surface of said silicon layer, a second section formed over and in contact with a second horizontal section of said top surface of said silicon layer, and a third section formed within said opening, wherein said third section formed within said opening comprises a first vertical portion formed on said first vertical sidewall surface, a second vertical portion formed on said second vertical sidewall surface, and a first horizontal portion formed on said horizontal bottom surface in contact with said top surface of said insulator layer, and wherein said first horizontal portion separates said first vertical portion from said second vertical portion.

11. The electrical structure of claim 10, wherein said first horizontal section, said second horizontal section, said first horizontal portion, said first vertical portion, said second vertical portion each comprise an equivalent thickness T1.

12. The electrical structure of claim 10, wherein said first horizontal section, said second horizontal section, and said first horizontal portion each comprise a first thickness T1, wherein said first vertical portion said second vertical portion each comprise a second thickness T2, wherein said first thickness T1 comprises a different thickness than said second thickness T2.

13. The electrical structure of claim 12, wherein said first thickness T1 is greater than said second thickness T2.

14. The electrical structure of claim 10, wherein said first horizontal section and said second horizontal section each comprise a first thickness T1, wherein said first horizontal portion comprises a second thickness T2, and wherein said first thickness T1 comprises a different thickness than said second thickness T2.

15. The electrical structure of claim 14, wherein said first thickness T1 is greater than said second thickness T2.

16. The electrical structure of claim 10, wherein said first horizontal section and said second horizontal section each comprise a first thickness T1, wherein said first horizontal portion comprise a second thickness T2, wherein said first vertical portion said second vertical portion each comprise a third thickness T3, wherein said first thickness T1 comprises a different thickness than said second thickness T2 and said third thickness T3, and wherein said second thickness T2 comprises a different thickness than and said third thickness T3.

17. The electrical structure of claim 16, wherein said first thickness T1 is greater than said second thickness T2, and wherein said second thickness T2 is greater than said third thickness T3.

18. The electrical structure of claim 16, wherein said first thickness T1 is greater than said second thickness T2, and wherein said second thickness T2 is less than said third thickness T3.

19. A method for forming an electrical structure comprising:
providing a semiconductor substrate;
forming an insulator layer over and in contact with said semiconductor substrate; and
forming a semiconductor fuse structure, wherein said fuse structure comprises a silicon layer and a continuous metallic silicide layer, and wherein said forming said semiconductor fuse structure comprises:
forming said silicon layer over and in contact with a top surface of said insulator layer,
forming an opening extending through a top surface of said silicon layer, wherein said opening comprises a horizontal bottom surface, a first vertical sidewall surface, and a second vertical sidewall surface; and
forming said continuous metallic silicide layer over said silicon layer, wherein said continuous metallic silicide layer comprises a first section formed over and in contact with a first horizontal section of said top surface of said silicon layer, a second section formed over and in contact with a second horizontal section of said top surface of said silicon layer, and a third section formed within said opening, wherein said third section formed within said opening comprises a first vertical portion formed on said first vertical sidewall surface, a second vertical portion formed on said second vertical sidewall surface, and a first horizontal portion formed on said horizontal bottom surface, and wherein said first horizontal portion separates said first vertical portion from said second vertical portion.

20. The method of claim 1, wherein said first horizontal section, said second horizontal section, said first horizontal portion, said first vertical portion, said second vertical portion each comprise an equivalent thickness T1.
